(19) United States
(12) Patent Application Publication
(10) Pub. No.: US 2026/0243820 A1
(43) Pub. Date: Aug. 20, 2026

(54) SEMICONDUCTOR PACKAGE TEST DEVICE WITH VERTICALLY ARRANGED PELTIER ELEMENTS

(71) Applicant: LIVINGCARE CO.,LTD., Daegu (KR)

(72) Inventors: Tage Ryul KWON, Daegu (KR); JunHyun PARK, Daegu (KR)

(21) Appl. No.: 19/488,769

(22) PCT Filed: Dec. 13, 2023
(86) PCT No.: PCT/KR2023/020515

§ 371 Date: Nov. 28, 2025

(30) Foreign Application Priority Data
Jan. 17, 2023 (KR) 10-2023-0006654

(51) Int. Cl. G01R 31/28

(52) U.S. Cl. CPC G01R 31/2877; G01R 31/2896

(57) ABSTRACT

A semiconductor package test device includes vertically arranged Peltier elements. The device includes a Peltier chamber in which a first Peltier block and a second Peltier block each including one or more vertically arranged Peltier elements are located, a pressurizing portion located above the Peltier chamber, coupled to a shaft having one side adjacent to the first Peltier block and the other side adjacent to the second Peltier block, and vertically moving the first Peltier block and the second Peltier block up and down so that a heat transfer block provided under the shaft presses a semiconductor package, a first water cooling jacket arranged on the opposite side of the shaft of the first Peltier block and cooling the first Peltier block, and a second water cooling jacket arranged on the opposite side of the shaft of the second Peltier block and cooling the second Peltier block.

### TECHNICAL FIELD

The present invention relates to a device for testing a semiconductor package, more specifically to a semiconductor package test device with vertically arranged Peltier elements that is capable of allowing the Peltier elements to be vertically arranged to test a semiconductor package more efficiently according to changes in temperature.

### BACKGROUND ART

A wafer contains hundreds of thousands of integrated circuit dies, after undergoing various semiconductor manufacturing processes, and the individual dies are isolated and then packaged, after their characteristics have been assessed. As a result, a semiconductor package for the die is made. The semiconductor package has to normally function in every environment. That is, the semiconductor package has to normally function at low or high temperature as well as at room temperature. However, some semiconductor packages do not function well or function abnormally at low or high temperature. In this case, they are sorted as defective products.

FIG. 1 is a schematic view showing a semiconductor package test device using Peltier elements in the prior art.

A conventional semiconductor package test device generally includes a plurality of Peltier chambers each having one or more Peltier elements located therein to adjust temperature and thus tests a plurality of semiconductor packages on test boards at a time. FIG. 1(a) is a schematic view showing a semiconductor package test device using Peltier elements in the prior art, and FIG. 1(b) is a perspective view showing the semiconductor package test device using Peltier elements in the prior art.

A general pitch between a first Peltier chamber 10 and a second Peltier chamber 20 is 60 mm, but if it is desired to absorb a relatively large amount of heat to allow the Peltier chambers to exert better structural cooling performance, a larger number of bigger Peltier elements than existing ones have to be used. In this case, the semiconductor package test device as suggested at present is required to increase the sizes of the Peltier chambers so that when the Peltier chambers increasing in size are arranged, a pitch between the test boards becomes undesirably narrow.

### DISCLOSURE

### Technical Problem

Accordingly, the present invention has been made in view of the above-mentioned problems occurring in the related art, and it is an object of the present invention to provide a semiconductor package test device that is capable of having a Peltier chamber in which Peltier elements are vertically arranged, without allowing a test board to increase in size or without any reduction in the number of Peltier chambers, thereby having better cooling performance than an existing test device.

### Technical Solution

To accomplish the above-mentioned object, according to the present invention, a semiconductor package test device may include: a Peltier chamber in which a first Peltier block and a second Peltier block each having one or more vertically arranged Peltier elements are located; a pressing part located above the Peltier chamber, coupled to a heat transfer member having one side facing the first Peltier block and the other side facing the second Peltier block, and moving the first Peltier block and the second Peltier block up and down so that a heat transfer block located on the underside of the heat transfer member presses a semiconductor package; a first water cooling jacket located on the side of the first Peltier block facing the heat transfer member to cool the first Peltier block; and a second water cooling jacket located on the side of the second Peltier block facing the heat transfer member to cool the second Peltier block.

Further, the pressing part may include a fixing member located above the Peltier chamber and a pressing member connected to the fixing member in such a way as to be coupled to the heat transfer member.

Furthermore, the heat transfer member may be configured to locate the heat transfer block on the underside thereof, and besides, the semiconductor package test device may further include pads for electrically connecting the semiconductor package thereto if the semiconductor package is pressed by means of the pressing part.

Additionally, the fixing member may be formed of a screw head, and the pressing member may have a screw thread on the outer periphery thereof.

### Advantageous Effects of Invention

According to the embodiment of the present invention, the Peltier elements are arranged with better space efficiency, thereby providing the semiconductor package test device with the vertically arranged Peltier elements that can improve the cooling capability while forming the pitch between the Peltier chambers on the test board to be equal to or less than in the prior art.

### BRIEF DESCRIPTION OF DRAWINGS

FIG. 1 is a schematic view showing a semiconductor package test device using Peltier elements in the prior art.

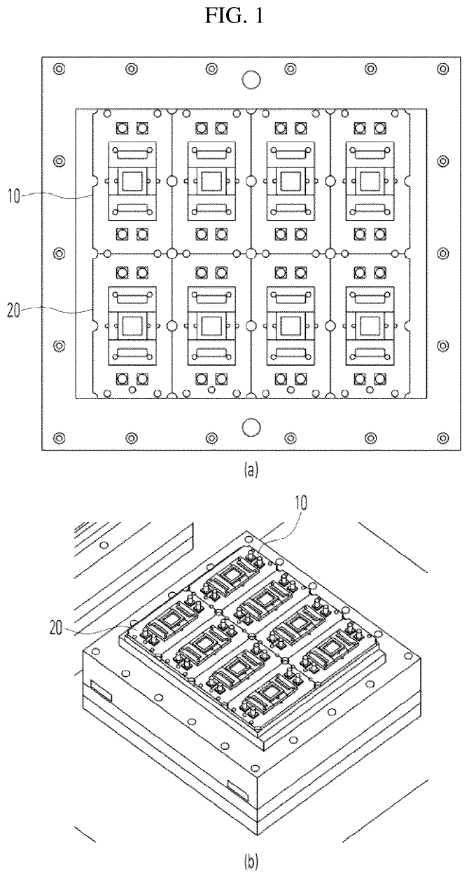

FIG. 2 is a schematic sectional view showing the semiconductor package test device using Peltier elements in the prior art, while performing a test for a semiconductor package.

FIG. 3 is a schematic sectional view showing the semiconductor package test device using Peltier elements in the prior art, wherein one or more Peltier chambers are arranged.

FIG. 4 is a schematic sectional view showing a semiconductor package test device with vertically arranged Peltier elements according to an embodiment of the present invention, while performing a test for a semiconductor package.

FIG. 5 is an exploded perspective view showing the coupling relation among water cooling jackets, Peltier blocks, and a heat transfer member of the semiconductor package test device with vertically arranged Peltier elements according to the embodiment of the present invention.

### BEST MODE FOR INVENTION

To accomplish the above-mentioned object, according to the present invention, a semiconductor package test device may include: a Peltier chamber in which a first Peltier block and a second Peltier block each having one or more vertically arranged Peltier elements are located; a pressing part located above the Peltier chamber, coupled to a heat transfer member having one side facing the first Peltier block and the other side facing the second Peltier block, and moving the first Peltier block and the second Peltier block up and down so that a heat transfer block located on the underside of the heat transfer member presses a semiconductor package; a first water cooling jacket located on the side of the first Peltier block facing the heat transfer member to cool the first Peltier block; and a second water cooling jacket located on the side of the second Peltier block facing the heat transfer member to cool the second Peltier block.

Further, the pressing part may include a fixing member located above the Peltier chamber and a pressing member connected to the fixing member in such a way as to be coupled to the heat transfer member.

Furthermore, the heat transfer member may be configured to locate the heat transfer block on the underside thereof, and besides, the semiconductor package test device may further include pads for electrically connecting the semiconductor package thereto if the semiconductor package is pressed by means of the pressing part.

Additionally, the fixing member may be formed of a screw head, and the pressing member may have a screw thread on the outer periphery thereof.

### Mode for Invention

Hereinafter, an embodiment of the present invention will be described with reference to the accompanying drawings. If it is determined that the detailed explanation on the well-known technology related to the present invention makes the scope of the present invention not clear, the explanation will be avoided for the brevity of the description. In the description of the present invention, given numerical values are just defined in the embodiment of the present invention.

Hereinafter, an explanation of the present invention will be given in detail. Before the present invention is disclosed and described, it is to be understood that the disclosed embodiments are merely exemplary of the invention, which can be embodied in various forms. In the description, it should be noted that the parts corresponding to those of the drawings are indicated by corresponding reference numerals.

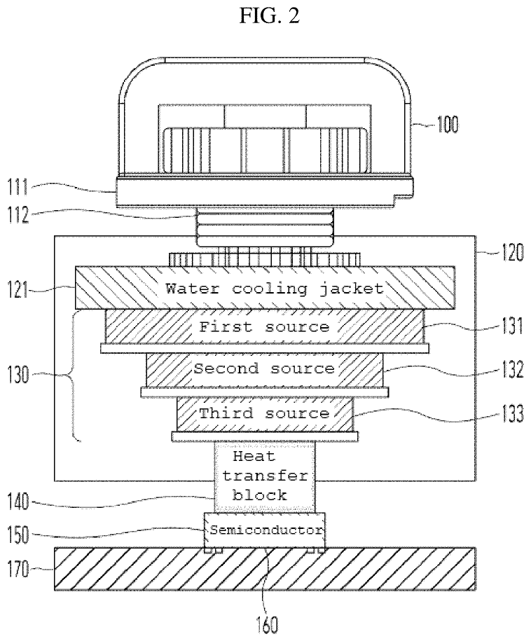

FIG. 2 is a schematic sectional view showing the semiconductor package test device using Peltier elements in the prior art, while performing a test for a semiconductor package.

The semiconductor package test device using Peltier elements in the prior art includes a Peltier chamber 120, a pressing part 100 located above the Peltier chamber 120 to face top of a water cooling jacket 121 located in the Peltier chamber 120 and thus to press the water cooling jacket 121 thereagainst, the water cooling jacket 121 located at a heat emission side of a Peltier block 130 constituted of one or more Peltier elements to cool the Peltier block 130, a heat transfer block 140 whose one side is joined face to face to the Peltier block 130 and thus fixed to the Peltier chamber 120 and the other side comes into contact with a semiconductor package 150 as a test target to allow heat transfer between the Peltier block 130 and the semiconductor package 150, the semiconductor package 150 in which one or more semiconductors are packaged through a process, one or more pads 160 located on the underside of the semiconductor package 150 and having electrical connectors for input and output of the semiconductor package 150 to determine whether the semiconductor package 150 generates the output with respect to the input accurately, and a test board 170 supporting the semiconductor package 150 against top thereof and allowing the pads 160 to be located on given regions of top thereof.

As shown in FIG. 2, cooling capability is provided through the Peltier elements, and to test whether the semiconductor package 150 functions even at a relatively low temperature, the Peltier block 130 has to have a larger number of Peltier elements than three Peltier elements, that is, first, second, and third Peltier elements 131, 132, and 133.

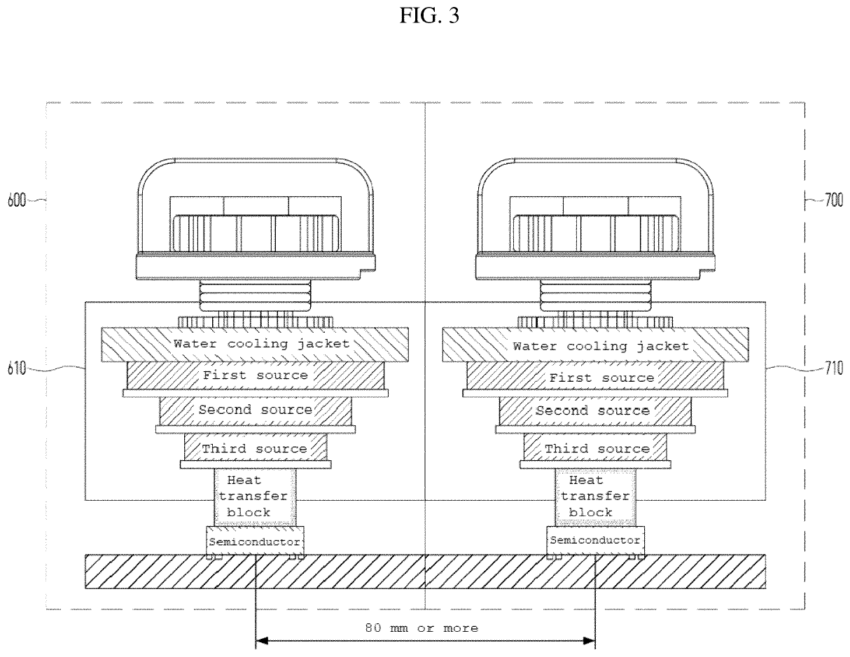

FIG. 3 is a schematic sectional view showing the semiconductor package test device using Peltier elements in the prior art, wherein one or more Peltier chambers are arranged.

A first test unit 600 is provided with a first Peltier chamber 610, and a second test unit 700 with a second Peltier chamber 710. A given pitch is kept between the test units adjacent to each other around their respective semiconductor packages. This is to prevent the neighboring Peltier chambers in which Peltier blocks each having one or more Peltier elements are located from overlapping each other.

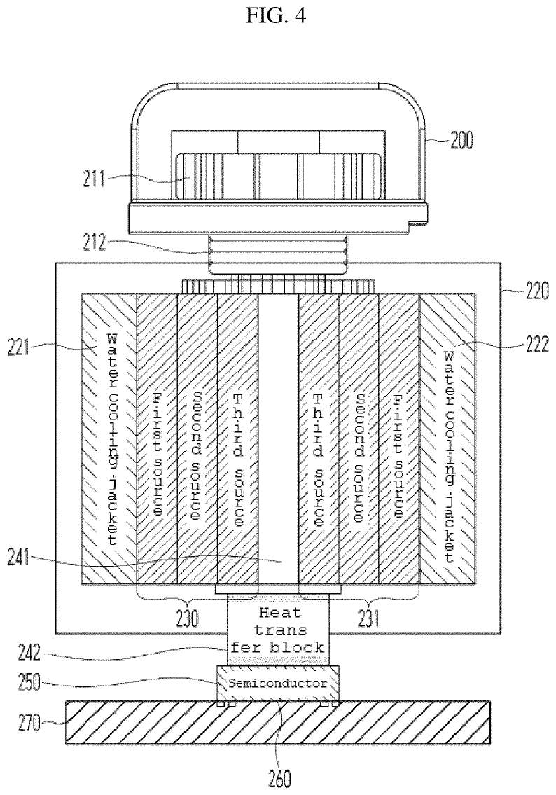

FIG. 4 is a schematic sectional view showing a semiconductor package test device with vertically arranged Peltier elements according to an embodiment of the present invention, while performing a test for a semiconductor package.

The semiconductor package test device with vertically arranged Peltier elements according to an embodiment of the present invention includes a Peltier chamber 220 in which the Peltier elements are vertically arranged, a pressing part 200 located above the Peltier chamber 220, vertically moving a first Peltier block 230, a second Peltier block 231, and a heat transfer member 241, and pressing a semiconductor package 250 through a heat transfer block 242, the first Peltier block 230 constituted of the one or more Peltier elements and located at one side of the heat transfer member 241, the second Peltier block 231 constituted of the one or more Peltier elements and located at the other side of the heat transfer member 241, first and second water cooling jackets 221 and 222 located at heat emission sides of the first and second Peltier blocks 230 and 231 to perform cooling for the first and second Peltier blocks 230 and 231, the heat transfer member 241 located to face the pressing part 200 and connected to the heat transfer block 232 to transfer the cool air emitted from the first Peltier block 230 and the second Peltier block 231 to the heat transfer block 242, the heat transfer block 242 whose one side is joined face to face to the heat transfer member 241 and thus fixed to the Peltier chamber 220 and the other side comes into contact with the semiconductor package 250 as a test target to allow heat transfer between the first and second Peltier blocks 230 and 231 and the semiconductor package 250, the semiconductor package 250 in which one or more semiconductors are packaged through a process, one or more pads 260 located on the underside of the semiconductor package 250 and having electrical connectors for input and output of the semiconductor package 250 to determine whether the semiconductor package 250 generates the output with respect to the input accurately, and a test board 270 supporting the semiconductor package 250 against top thereof and allowing the pads 260 to be located on given regions of top thereof.

According to the embodiment of the present invention, the pressing part 200 includes a fixing member 211 and a pressing member 212, and the fixing member 211 is located on the upper portion of the pressing part 200 and formed of a screw fastener. In this case, the pressing member 212 has a screw thread on the outer periphery thereof, and a lower portion of the pressing member 212 has the shape of a plate and is thus coupled to the heat transfer member 241 in such a way as to allow the first Peltier block 230, the second Peltier block 231, and the heat transfer member 241 to move up and down.

According to the embodiment of the present invention, an electric current is applied when the electrical connectors (not shown) of the pads 260 are joined to the input and output terminals of the semiconductor package 250, and the input and output terminals of the semiconductor package 250 have the shapes of balls. The electrical connectors are concavely formed on the pads 260 in such a way as to insert the balls thereinto. In this case, the heat transfer block 242 is joined to the semiconductor package 250 in such a way as to be pressed face to face against top of the semiconductor package 250.

In this case, the first Peltier block 230 and the second Peltier block 231 each have one or more Peltier elements and thus make use of the Peltier effect to generate heat or cool air. The Peltier effect is a thermoelectric phenomenon where heat is either absorbed or released at the junction of two different conductors when an electric current flows through them. This effect results in one junction cooling down while the other heats up.

Each Peltier element of the first Peltier block 230 is provided with a first electrode and a second electrode, and the electric current is applied to the first electrode and the second electrode through an external interface. Further, polarities applied to the first electrode and the second electrode are changed to allow heat or cool air to be emitted down (which is not shown).

As shown in FIG. 4, the respective Peltier elements are arranged vertically with respect to the floor so that their surface relatively close to the heat transfer member 241 cools down and their surface relatively distant from the heat transfer member 241 heats up.

If the Peltier elements are multi-stacked on top of one another, the first Peltier block 230 and the second Peltier block 231 may become colder. According to the prior art, if the sizes of the Peltier elements increase to improve the cooling performance, the horizontal size of the Peltier chamber becomes big. According to the embodiment of the present invention, however, if the Peltier elements are arranged vertically in the Peltier chamber, the Peltier chamber becomes big in vertical size, not in horizontal size. According to the embodiment of the present invention, as a result, an interval between the Peltier chambers does not increase over a current interval.

According to the embodiment of the present invention, further, the Peltier elements are arranged symmetrically on both sides of the Peltier chamber 220 so that they can reach a predetermined temperature more quickly than in the prior art.

In the description of the embodiment of the present invention, up to now, the upper sides of the Peltier elements emit heat to the outside of the Peltier chamber 220, but if the polarities of the first electrode and the second electrode are changed, one side of each Peltier element constituting the Peltier blocks 230 and 231, which is distant from the heat transfer member 241, generates cool air, and the other side close to the heat transfer member 241 generates heat so that the heat is transferred to the semiconductor package 250 through the heat transfer block 242. In this case, the cooling water existing in the first water cooling jacket 221 and the second water cooling jacket 222 has a temperature higher than a temperature on the surface facing the Peltier element, so that the cool air is emitted to the outside of the Peltier chamber 220.

The current advancement of information processing technology necessitates the development of higher-performance semiconductors, and therefore, current technologies are focusing on improving semiconductor performance by packaging semiconductors multi-layered on the same area. In the case of a memory semiconductor, further, multi-layering of NAND flash memories is a measure of the technical skills, and even in the case of a non-memory semiconductor, a FinFET or Gate-All-Around 3D semiconductor technology has been continuously studied and developed. As an amount of data processed per one semiconductor package increases, at present, a more reliable performance test is needed, and such a reliability test for semiconductor packages takes up a large portion in semiconductor manufacturing post-processes.

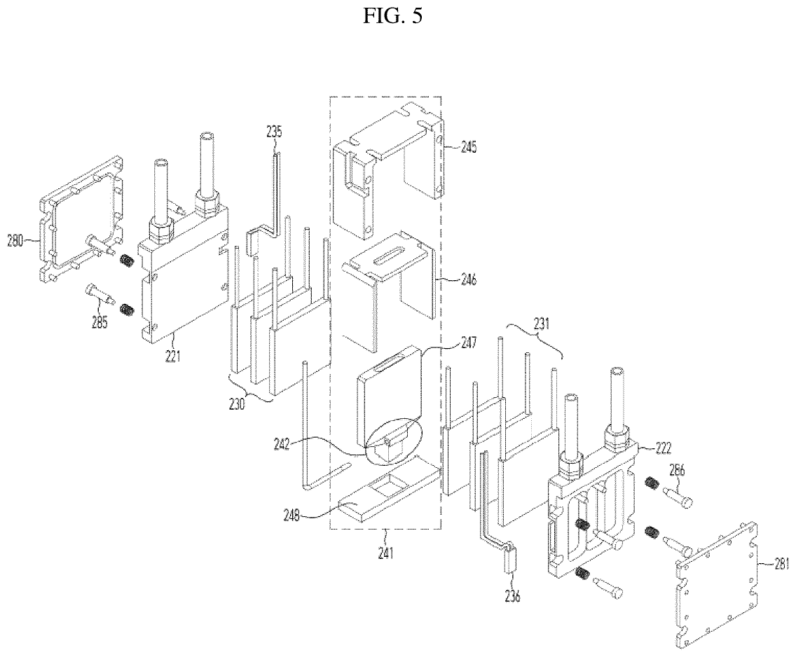

FIG. 5 is an exploded perspective view showing the coupling relation among the water cooling jackets, the Peltier blocks, and the heat transfer member of the semiconductor package test device with vertically arranged Peltier elements according to the embodiment of the present invention.

The heat transfer member 241 includes a first member 245, a second member 246, a third member 247, and an underside member 248, and the first member 245 receives the second member 246 and the third member 247 therein and is fixed on top thereof to the pressing member 212 of the pressing part 200.

Further, the second member 246 receives the third member 247 therein, and the heat transfer block 242 is located on the underside of the third member 247.

The underside member 248 has a hollow hole at the inside thereof in such a way as to fixedly insert the heat transfer block 242 thereinto and has the shape of a plate on the outside around the hollow hole in such a way as to support the first member 245, the second member 246, and the underside member 248 thereagainst.

The first Peltier block 230 is located at one side of the heat transfer member 241, and the second Peltier block 231 is located at the other side of the heat transfer member 241 in such a way as to be symmetrical with the first Peltier block 230. Further, the first water cooling jacket 221 is located at the outside of the first Peltier block 230, while the second water cooling jacket 222 is being located at the outside of the second Peltier block 231, and a first side wall 280 is located at the outside of the first water cooling jacket 221 to allow the first water cooling jacket 221 to be fastened to the first member 245 by means of first fastening means 285, while a second side wall 281 is being located at the outside of the second water cooling jacket 222 to allow the second water cooling jacket 222 to be fastened to the first member 245 by means of second fastening means 286. Accommodation portions defined as given spaces are formed at the insides of the first water cooling jacket 221 and the second water cooling jacket 222 to allow the first Peltier block 230 to be fixable between the first water cooling jacket 221 and the heat transfer member 241 and to allow the second Peltier block 231 to be fixable between the second water cooling jacket 222 and the heat transfer member 241.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

### Industrial Applicability of the Invention

The present invention relates to the semiconductor package test device with vertically arranged Peltier elements, the device including: the Peltier chamber in which the first Peltier block and the second Peltier block each having one or more vertically arranged Peltier elements are located; the pressing part located above the Peltier chamber, coupled to the heat transfer member having one side facing the first Peltier block and the other side facing the second Peltier block, and moving the first Peltier block and the second Peltier block up and down so that the heat transfer block located on the underside of the heat transfer member presses the semiconductor package; the first water cooling jacket located on the side of the first Peltier block facing the heat transfer member to cool the first Peltier block; and the second water cooling jacket located on the side of the second Peltier block facing the heat transfer member to cool the second Peltier block.

Accordingly, the Peltier elements are arranged with better space efficiency, thereby providing the semiconductor package test device with the vertically arranged Peltier elements that can improve the cooling capability while forming the pitch between the Peltier chambers on the test board to be equal to or less than in the prior art.

1. A semiconductor package test device comprising:
a Peltier chamber in which a first Peltier block and a second Peltier block each having one or more vertically arranged Peltier elements are located;
a pressing part located above the Peltier chamber, coupled to a heat transfer member having one side facing the first Peltier block and the other side facing the second Peltier block, and moving the first Peltier block and the second Peltier block up and down so that a heat transfer block located on the underside of the heat transfer member presses a semiconductor package;
a first water cooling jacket located on the side of the first Peltier block facing the heat transfer member to cool the first Peltier block; and
a second water cooling jacket located on the side of the second Peltier block facing the heat transfer member to cool the second Peltier block.

2. The semiconductor package test device according to claim 1, wherein the pressing part comprises:
a fixing member located above the Peltier chamber; and
a pressing member connected to the fixing member in such a way as to be coupled to the heat transfer member.

3. The semiconductor package test device according to claim 1, wherein the heat transfer member is configured to locate the heat transfer block on the underside thereof.

4. The semiconductor package test device according to claim 1, further comprising pads for electrically connecting the semiconductor package thereto if the semiconductor package is pressed by means of the pressing part.

5. The semiconductor package test device according to claim 2, wherein the fixing member is formed of a screw head, and the pressing member has a screw thread on the outer periphery thereof.
